(19) United States
(12) Patent Application Publication
(10) Pub. No.: US 2026/0206231 A1
(43) Pub. Date: Jul. 16, 2026

(54) SEMICONDUCTOR DEVICE AND METHOD FOR FABRICATING THE SAME

(71) Applicant: SK hynix Inc., Gyeonggi-do (KR)

(72) Inventors: Young Ki CHAI, Gyeonggi-do (KR); Jung Hyeok KWAK, Gyeonggi-do (KR); Tae Yup KIM, Gyeonggi-do (KR); Ku Youl JUNG, Gyeonggi-do (KR); Jin Won JUNG, Gyeonggi-do (KR)

(21) Appl. No.: 19/257,476

(22) Filed: Jul. 2, 2025

(30) Foreign Application Priority Data
Jan. 15, 2025 (KR) 10-2025-0005831

(51) Int. Cl. H10B 61/00; H10N 50/01; H10N 50/10; H10N 50/85

(52) U.S. Cl. CPC H10B 61/10; H10N 50/01; H10N 50/10; H10N 50/85

(57) ABSTRACT

Provided are a semiconductor device, and a method for fabricating the same. The semiconductor device in accordance with an embodiment of the present disclosure includes: a substrate; and a memory layer formed over the substrate, wherein the memory layer includes a magnetic tunnel junction (MTJ) pattern, including a plurality of magnetic layer patterns and a tunnel barrier layer pattern, and wherein sidewalls of the magnetic layer patterns and the tunnel barrier layer pattern are aligned perpendicularly to a plane of the substrate.

### CROSS-REFERENCE TO RELATED APPLICATIONS

The present application claims priority under 35 U.S.C 119(a) to Korean Patent Application No. 10-2025-0005831, filed on Jan. 15, 2025, which is incorporated herein by reference in its entirety.

### BACKGROUND

### 1. Field

Various embodiments of the present invention relate to a semiconductor technology, and more particularly, to a semiconductor device including a magnetic tunnel junction (MTJ) structure, and a method for fabricating the semiconductor device.

### 2. Description of the Related Art

Recent demands for miniaturization, low power consumption, high performance, and diversification of electronic devices require semiconductor devices capable of storing data in diverse electronic devices, such as computers, portable communication devices and the like. Researchers and the industry are studying to develop semiconductor devices that fulfill these requirements, including ones capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments according to the present disclosure are directed to a device that is fabricated by patterning a magnetic tunnel junction (MTJ) layer without an ion beam etching (IBE) process by performing an imprinting process, and a method for fabricating the semiconductor device. The embodiments of the present disclosure provides benefits such as preventing the limitation in securing process margins, the limitation in the incident angle of an argon (Ar) beam, an electrical short circuit defect, referred to as a shorting failure rate (SFR), of an MTJ pattern, and physical damage to the MTJ sidewall, due to the IBE process that is often used in a process of patterning a general MTJ layer.

In accordance with an embodiment of the present invention, a semiconductor device includes: a substrate; and a memory layer formed over the substrate, wherein the memory layer includes a magnetic tunnel junction (MTJ) pattern, including a plurality of magnetic layer patterns and a tunnel barrier layer pattern, and wherein sidewalls of the magnetic layer patterns and the tunnel barrier layer pattern are aligned perpendicularly to a plane of the substrate.

In accordance with another embodiment of the present invention, a method for fabricating a semiconductor device includes: forming a guide pattern having a resist pattern arrayed over a substrate by an imprinting process; forming a memory layer in a recessed portion of the resist pattern; and forming a memory layer pattern by removing the guide pattern.

### BRIEF DESCRIPTION OF THE DRAWINGS

FIGS. 1A to 1D are cross-sectional views illustrating an imprint stamper having an embossed pattern and a method for forming the same in accordance with an embodiment of the present disclosure.

FIGS. 2A to 2B are cross-sectional views illustrating a process structure in which a resist layer is applied onto an etch target layer and a method for forming the same in accordance with an embodiment of the present disclosure.

FIGS. 3A to 3C are cross-sectional views illustrating a method for forming a guide pattern in accordance with an embodiment of the present disclosure.

FIGS. 4A and 4B are cross-sectional views illustrating a semiconductor device and a method for fabricating the same in accordance with an embodiment of the present disclosure.

FIGS. 5A and 5B are cross-sectional views illustrating a semiconductor device and a method for fabricating the same in accordance with another embodiment of the present disclosure.

### DETAILED DESCRIPTION

Hereinafter, the various embodiments of the present disclosure will be described in detail with reference to the attached drawings.

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

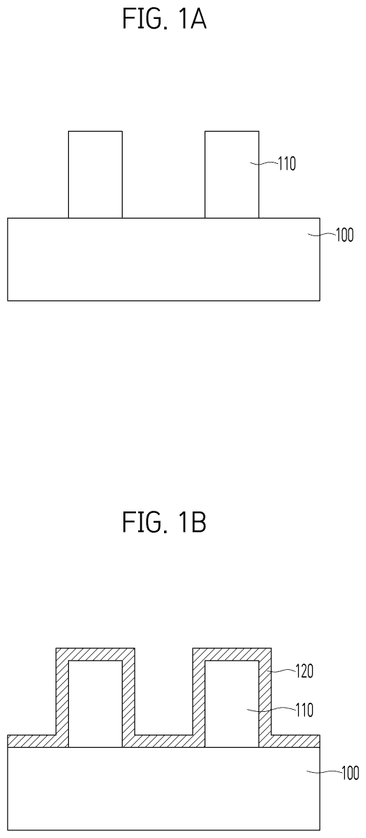

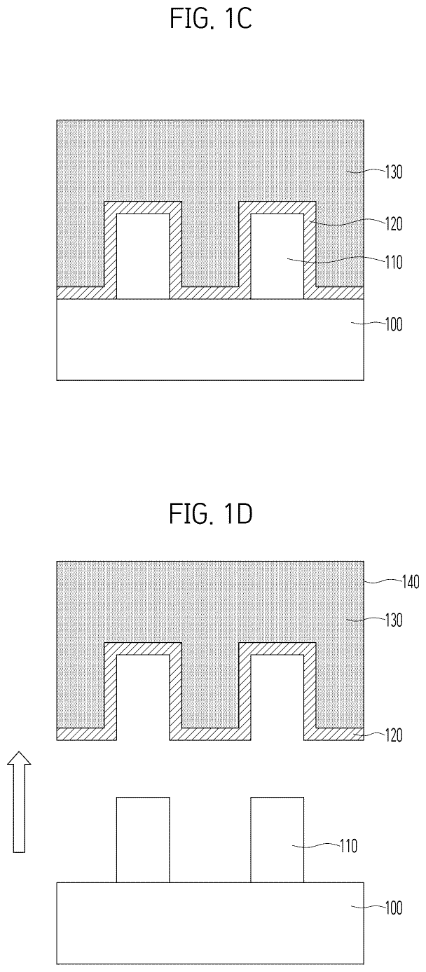

FIGS. 1A to 1D are cross-sectional views illustrating an imprint stamper having an embossed pattern and a method for forming the same in accordance with an embodiment of the present disclosure. This stamper may be used in a method for fabricating a semiconductor device in accordance with an embodiment of the present disclosure.

Referring to FIG. 1A, a plurality of embossed patterns 110 may be formed over a first substrate 100. The first substrate 100 may include a semiconductor material, for example, silicon and the like. A required predetermined lower structure may be formed in the first substrate 100.

First, a resist may be uniformly applied to the first substrate 100, and after the resist is applied, the resist may be partially cured by heating the first substrate 100. This may help increase the adhesive force of the resist and maintain a uniform thickness. The resist may include a thermosetting resin or an ultraviolet (UV)-curable resin. The thickness of the applied resist may be adjusted according to the process requirements, and the resist may be applied with a uniform thickness, which may be important for increasing the precision of the pattern formation. Subsequently, a mask or reticle may be used to expose the resist to light, such as ultraviolet rays or extreme ultraviolet rays, through a desired pattern shape to form a resist pattern. An embossed pattern 110 may be formed by selectively etching the substrate 100 with the resist pattern used as a mask and removing the resist remaining after the etching process. This etching process may be a dry etching process that forms a highly precise pattern by using plasma or an ion beam, or a wet etching process that selectively removes a material by using a chemical solution. After the etching process, when the remaining resist is completely removed by using a chemical remover or performing a plasma treatment, only the embossed pattern 110 may remain in the first substrate 100. The embossed pattern 110 may include silicon, silicon oxide (SiO₂), silicon nitride (Si₃N₄), a metal, such as copper or aluminum.

Referring to FIG. 1B, a conductive layer 120 may be formed over the embossed pattern 110. The conductive layer 120 may include at least one selected from the group including nickel (Ni), copper (Cu), silver (Ag), and gold (Au). The conductive layer 120 may be formed by sputtering, electroplating, chemical vapor deposition, or evaporation deposition. The conductive layer 120 may have a thickness of approximately 10 nm to 100 nm. The thickness of the conductive layer 120 may be optimized for easily separating a stamper (e.g., a stamper 140 of FIG. 1D) and maintaining the pattern shape on the surface of the substrate 100. When the conductive layer 120 has a thickness of approximately 10 to 50 nm, the contact area with the stamper may be minimized to lower the adhesive force and the stamper may be separated easily. When the conductive layer 120 is too thin, there is a possibility that a defect may occur due to the uneven coating. When the conductive layer 120 has a thickness of approximately 50 to 100 nm, it may provide stable contact with the surface of the stamper and prevent damage to the substrate and the pattern. When the conductive layer 120 is too thick, unnecessary stress may be caused when the stamper is separated.

Referring to FIGS. 1C and 1D, a plating layer 130 may bury the embossed pattern 110. The plating layer 130 may be formed of one selected from the group including dielectric materials such as aluminum oxide (Al₂O₃), tungsten oxide (WO₃) and magnesium oxide (MgO), metal materials such as copper (Cu), silver (Ag), aluminum (Al), cobalt (Co) and nickel (Ni), transparent materials such as glass, sapphire and quartz, and polymer materials such as polyimide, polycarbonate, polyethylene and polypropylene.

The plating layer 130 may be formed by electroplating, which includes immersing metal ions in an electrolyte solution and precipitating the plating layer 130 in chemical vapor deposition (CVD), or sputtering. The plating layer 130 may be formed by electroplating, which may include immersing metal ions in an electrolyte solution and precipitating the plating layer 130 in a concave portion of the embossed pattern 110 based on an electric current. The electroplating may be a method of immersing metal ions in an electrolyte solution and precipitating the plating layer 130 in a concave portion of the embossed pattern 110 based on an electric current.

First, a solution that includes metal ions in an electrolyte solution for electroplating may be prepared. This solution may include a metal to be plated, such as nickel, copper, silver and the like. When the first substrate 100 is immersed in the electrolyte solution and an electric current is applied to the electrolyte solution, the metal ions may be selectively deposited in the concave portion of the embossed pattern 110 of the first substrate 100. The thickness of the plating layer 130 may be controlled according to the intensity and time of the current. When the electric current flows, a metal may accumulate in the concave portion of the embossed pattern 110, thereby filling the concave portion of the embossed pattern 110 with the plating layer 130. Since this method forms the plating layer 130 uniformly according to the shape of the embossed pattern 110, it may ensure accurate filling.

Chemical vapor deposition is a method of forming a solid metal layer by depositing a gaseous compound onto the substrate at a high temperature. This method may be mainly used to uniformly form a thin metal layer or fill a fine structure. First, a gaseous compound suitable for the chemical vapor deposition (CVD) process may be prepared. In this case, for example, a metal organic compound may be used. The first substrate 100 on which the embossed pattern 110 is formed may be placed in a CVD reactor. The gaseous metal compound may react with the surface of the embossed pattern 110 in a high temperature environment to deposit the metal. Through this process, the plating layer 130 may be formed in the concave portion of the embossed pattern 110. According to the CVD process, a uniform and high-density plating layer may be formed. Further, the plating layer with even a very thin thickness may be accurately formed, and this plating layer may be effectively applied to complex shapes or fine patterns.

Sputtering may be a method of depositing a metal onto the surface of the substrate by shooting high-energy particles at the substrate, and the sputtering may be mainly used when a thin metal layer is formed. First, a desired metal, such as nickel, copper and the like, may be prepared as a target, and high-energy particles may be shot at the first substrate 100 on which the embossed pattern 110 is formed so that the metal may be deposited from the target to the substrate 100. Here, the plating layer 130 may be formed in the concave portion of the embossed pattern 110, and when the sputtering is completed, a metal may be uniformly deposited onto the embossed pattern 110 to form the plating layer 130. According to this method, a plating layer with a fine pattern or a uniform thickness may be formed and may be applied to diverse materials.

Subsequently, the plating layer 130 whose surface is covered with the conductive layer 120 may be separated from a disk that is formed of the first substrate 100 and the embossed pattern 110 to form the stamper 140 having an engraved pattern. That is, the stamper 140 may include the conductive layer 120 and the plating layer 130 and may have an engraved pattern structure.

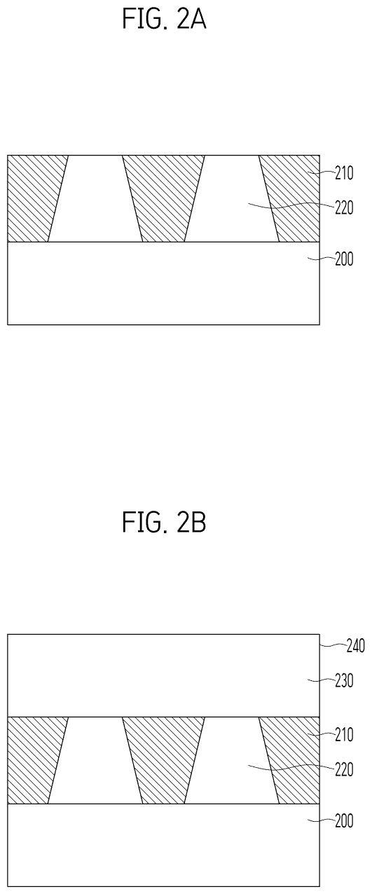

FIGS. 2A to 2B are cross-sectional views illustrating a method for forming a resist layer over the substrate in accordance with an embodiment of the present disclosure.

Referring to FIG. 2A, a lower electrode contact 210 may be formed over a second substrate 200 on which a predetermined lower structure is formed. The lower electrode contact 210 may be formed by forming an inter-layer dielectric layer 220 having a hole over the second substrate 200, forming a material layer for forming the lower electrode contact 210 in the hole, and then performing a planarization process, for example, a chemical mechanical planarization process on the material layer. The inter-layer dielectric layer 220 may include a dielectric material, polysilicon (Poly-Si), or a combination thereof. The inter-layer dielectric layer 220 may be formed as a single-layer structure or a multi-layer structure. For example, the inter-layer dielectric layer 220 may include silicon oxide, silicon nitride, silicon oxynitride, and/or a low-k material. Materials having a dielectric constant (k) of approximately 4 or less may be generally referred to as low-k materials. As the value of the dielectric constant (k) of the inter-layer dielectric layer 220 becomes smaller, the electrical insulation characteristics of the inter-layer dielectric layer 220 may be improved to decrease the parasitic capacitance between elements. Such low-k materials may include silicon oxide, organic siloxane, silicon carbide, organic-based materials including a benzene ring or fluorine, and porous materials, but the concept and spirit of the present disclosure are not limited thereto.

This process may be performed by creating a hole of a fine size at a location where the lower electrode contact 210 is to be disposed through a photolithography process and an etching process, and filling the hole with the material layer for forming the lower electrode contact 210. The materials for forming the lower electrode contact 210 may include tungsten (W), titanium (Ti), tantalum (Ta), vanadium (V), chromium (Cr), platinum (Pt), aluminum (Al), copper (Cu), zinc (Zn), nickel (Ni), cobalt (Co), lead (Pd), manganese (Mn), niobium (Ni), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), or a combination thereof.

Referring to FIG. 2B, a resist layer 230 may be formed over the planarized lower electrode contact 210 and the inter-layer dielectric layer 220, and an etch target layer 240 may be subsequently formed on the resist layer 230.

The resist layer 230 may be formed by spin coating, slot die coating, spray coating, or immersion coating. For example, a thin and uniform resist layer 230 may be formed by dropping a liquid-state resist on the surface of the inter-layer dielectric layer 220 and rotating the substrate 200 at a high speed to apply the liquid-state resist to a uniform thickness.

To form the resist layer 230, a thermosetting resin such as polyimide or polymethyl methacrylate (PMMA), a UV-curable resin such as acrylate or epoxy, or a photoresist such as a positive resist or a negative resist may be used. Polyimide having a high heat-resistance may be suitable for a high-temperature process, and polymethyl methacrylate may be mainly used for electron beam lithography. Acrylate has a fast photocuring reaction speed and a high pattern resolution, and epoxy having a high strength and excellent durability may be suitable for fine patterns. Also, a portion of the positive resist that is exposed to UV light may be removed by a developer (for example, a developer solution), and the positive resist may be advantageous for forming a high-resolution pattern. A portion of the negative resist that is not exposed to UV light may be removed by a developer.

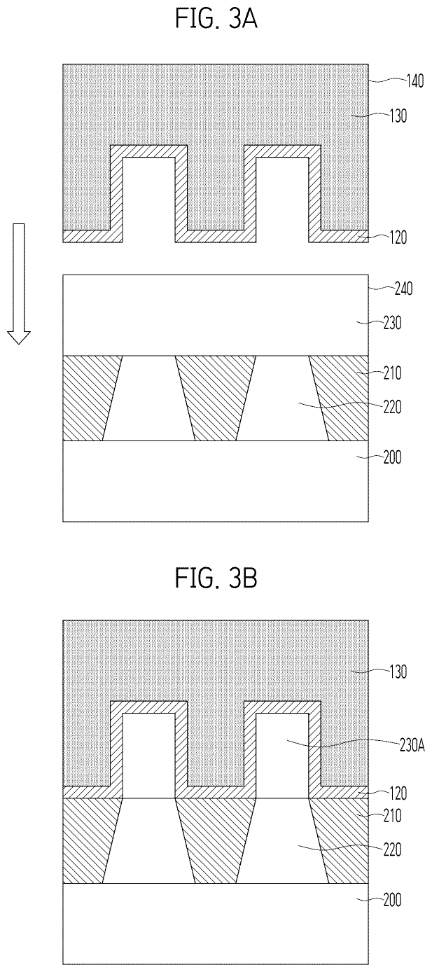

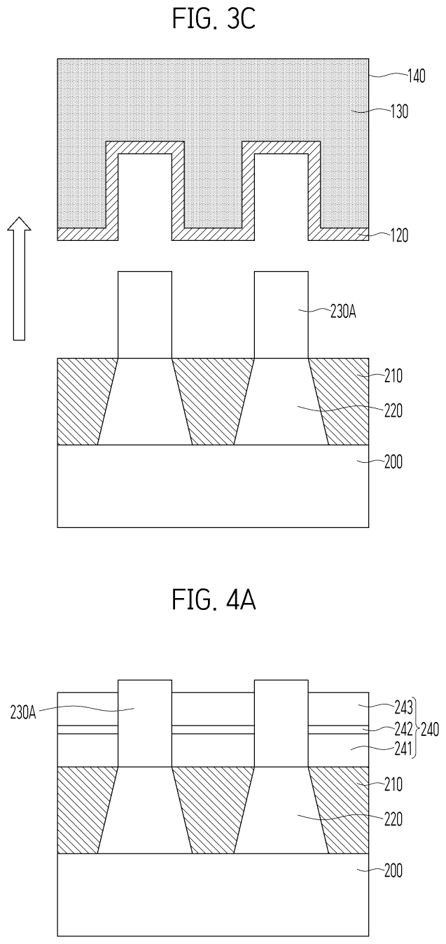

FIGS. 3A to 3C are cross-sectional views illustrating a method for forming a guide pattern in accordance with an embodiment of the present disclosure.

Referring to FIGS. 3A and 3B, a resist pattern 230A may be formed by imprinting the resist layer 230 of the etch target layer 240 formed in FIG. 2B with the stamper 140 having the negative pattern formed in FIG. 1D used therein and thereby transferring the shape of the pattern of the stamper 140 to the resist layer 230.

The stamper 140 having the negative pattern formed in FIG. 1D may be designed to maintain a high-resolution fine structure, and may additionally go through a cleaning process and a coating process to prevent surface contamination. In particular, the conductive layer 120 may be formed in the lower portion of the stamper 140. This conductive layer 120 may function to induce electrostatic discharge that may occur during the separation process, and alleviate the adhesive force between the stamper 140 and the resist layer 230. This may reduce the possibility of pattern damage during the separation process and increase the shape transferring efficiency.

The resist layer 230 of the etch target layer 240 formed in FIG. 2B and the stamper 140 may be precisely aligned. The alignment may be performed using high-precision alignment equipment so that the shape of the pattern of the stamper 140 may be accurately transferred to the target location over the resist layer 230. The stamper 140 and the etch target layer 240 may be bonded so that the conductive layer 120 of the stamper 140 and the resist layer 230 of the etch target layer 240 may face each other. The stamper 140 may be pressed onto the resist layer 230 so that the resist layer 230 is deformed to fit into the engraved pattern of the stamper 140. In this instance, a predetermined pressure may be applied uniformly so that the resist layer 230 may completely fill the pattern of the stamper 140. In a state where the pattern is formed by pressing the resist layer 230 with the stamper 140, the resist may be cured using ultraviolet (UV) light or heat.

Referring to FIG. 3C, after the resist layer 230 is completely cured, the stamper 140 may be separated. Here, the conductive layer 120 in the lower portion of the stamper 140 may play an important role. That is, the conductive layer 120 may discharge the static electricity that may be generated during the separation process, thereby reducing the electrostatic attraction between the stamper 140 and the resist pattern 230A. This may prevent the resist pattern 230A from sticking to the stamper 140 and minimize damage during the separation process. Also, the conductive layer 120 may work together with a non-adhesive coating, such as a fluorine-based coating, to make the separation of the stamper 140 easier. After the stamper 140 is removed, the shape of the negative pattern of the stamper 140 may be directly transferred to the resist layer 230 to form the resist pattern 230A. Here, the upper surface of the lower electrode contact 210 disposed between the resist patterns 230A may be exposed.

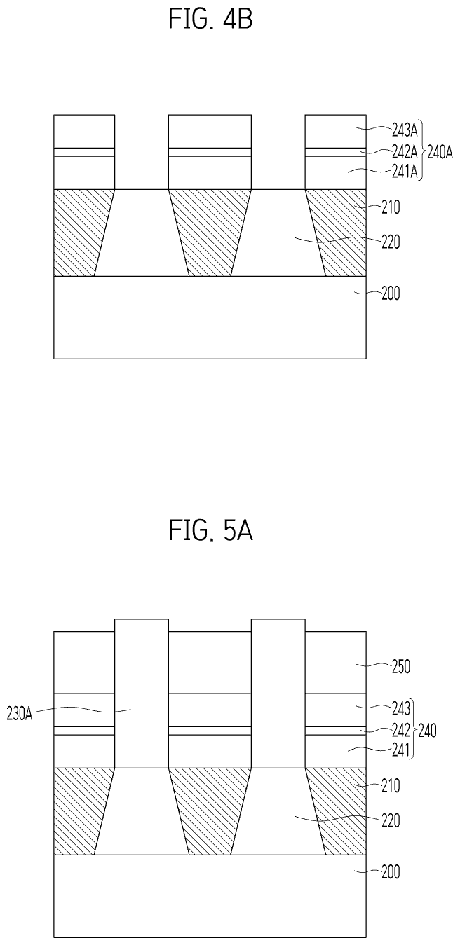

FIGS. 4A and 4B are cross-sectional views illustrating a semiconductor device and a method for fabricating the same in accordance with an embodiment of the present disclosure.

Referring to FIG. 4A, a memory layer including a plurality of magnetic layers may be formed over the lower electrode contact 210 exposed in the recessed portion between the resist patterns 230A formed in FIG. 3D. In other words, an MTJ layer 240 including a fixed layer 241, a tunnel barrier layer 242, and a free layer 243 may be formed sequentially over the lower electrode contact 210. Here, the fixed layer 241 may contact the lower electrode contact 210.

Referring to FIG. 4B, a lift-off process of removing the resist pattern 230A to leave only a desired memory layer pattern, for example, an MTJ pattern 240A, may be performed. This memory layer pattern may include a memory layer pattern, and may be, for example, an MTJ pattern 240A including a plurality of magnetic layer patterns.

First, an appropriate solvent capable of easily dissolving the resist pattern 230A may be prepared. The process structure including the resist pattern 230A formed over the lower electrode contact 210 and the inter-layer dielectric layer 220 may be immersed in an organic solvent capable of dissolving the resist pattern 230A, such as acetone or NMP (N-methyl-2-pyrrolidone). Alternatively, the solvent may be applied to the resist pattern 230A by spraying. As the solvent permeates and dissolves the resist pattern 230A, the resist pattern 230A may be removed.

The residue of the resist pattern 230A remaining after the solvent treatment may be cleanly removed, for example, using an ultrasonic treatment or a deionized water. When the resist pattern 230A is completely removed, only the MTJ pattern 240A between the spaces where the resist pattern 230A used to be may remain. As a result, the MTJ pattern 240A formed of a plurality of magnetic layer patterns including a fixed layer pattern 241A, a tunnel barrier layer pattern 242A, and a free layer pattern 243A may be formed over the lower electrode contact 210.

After the lift-off process is completed, an additional process (or processes) such as an annealing process or a protective layer forming process may be performed to ensure the stability and quality of the MTJ pattern 240A. The annealing process may be applied to improve the magnetic characteristics of the MTJ pattern 240A and the quality of the tunnel barrier layer pattern 242A. Also, a protective layer may be formed of carbon (C) or silicon oxide (SiO₂) to prevent physical and chemical damage to the MTJ pattern 240A. Through this process, the MTJ pattern 240A may be formed in a state in which the MTJ pattern 240A is precisely aligned with the lower electrode contact 210. The precisely aligned MTJ pattern 240A may be applied to diverse applications such as a magnetic random access memory (MRAM) or a magnetic sensor.

The memory layer including the MTJ pattern 240A may function to store data in diverse ways. For example, the memory layer may include a variable resistance layer that stores different data by switching between different resistance states according to the voltage or current supplied through the upper and lower ends of the memory layer. The variable resistance layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM), and the like, for example, metal oxides such as transition metal oxides, perovskite-based materials and the like, phase-change materials such as chalcogenide-based materials, ferroelectric materials, ferromagnetic materials, and the like.

The free layer pattern 243A and the fixed layer pattern 241A may include materials having interface perpendicular magnetic anisotropy. Interface perpendicular magnetic anisotropy may refer to a phenomenon in which a magnetic layer having intrinsic horizontal magnetization characteristics has a vertical magnetization direction due to the influence from the interface with another layer which is adjacent to the magnetic layer. Here, the intrinsic horizontal magnetization characteristics may mean that, in the absence of an external factor, the magnetic layer has a magnetization direction which is parallel to the widest surface of the magnetic layer. For example, when a magnetic layer having the intrinsic horizontal magnetization characteristics is formed over a substrate and there are no external factors, the magnetization direction of the magnetic layer may be substantially parallel to the upper surface of the substrate. Each of the free layer pattern 243A may have a changeable magnetization direction and the fixed layer pattern 241A having a fixed magnetization direction may have a single-layer structure or a multi-layer structure including a ferromagnetic material. The ferromagnetic material may include an alloy containing iron (Fe), nickel (Ni) or cobalt (Co) as a main component, for example, an iron-platinum (Fe—Pt) alloy, an iron-palladium (Fe—Pd) alloy, a cobalt-iron (Co—Fe) alloy, a cobalt-palladium (Co—Pd) alloy, a cobalt-platinum(Co—Pt) alloy, a cobalt-iron-nickel (Co—Fe—Ni) alloy, an iron-nickel-platinum (Fe—Ni—Pt) alloy, a cobalt-iron-platinum (Co—Fe—Pt) alloy, a cobalt-nickel-platinum (Co—Ni—Pt) alloy, a cobalt-iron-boron (Co—Fe—B) alloy, and the like, or may include a stacked structure such as cobalt/platinum (Co/Pt) or cobalt/palladium (Co/Pd).

The positions of the free layer pattern 243A and the fixed layer pattern 241A may be switched with each other with the tunnel barrier layer pattern 242A interposed between them. In other words, the free layer pattern 243A may be disposed below the tunnel barrier layer pattern 242A, and the fixed layer pattern 241A may be disposed over the tunnel barrier layer pattern 242A. The tunnel barrier layer pattern 242A may enable tunneling of electrons between the free layer pattern 243A and the fixed layer pattern 241A during a write operation that changes the resistance state of the variable resistor element, thereby changing the magnetization direction of the free layer pattern 243A. The tunnel barrier layer pattern 242A may include at least one among an oxide of magnesium (Mg), an oxide of titanium (Ti), an oxide of aluminum (Al), an oxide of magnesium-zinc (MgZn), an oxide of magnesium-boron (MgB), a nitride of titanium (Ti), and a nitride of vanadium (V). For example, the tunnel barrier layer pattern 242A may be a single layer of magnesium oxide (MgO). Also, the tunnel barrier layer pattern 242A may include a plurality of layers. The free layer pattern 243A, the tunnel barrier layer pattern 242A, and the fixed layer pattern 241A may form the MTJ pattern 240A.

The electrical resistance of the MTJ pattern 240A may depend on the magnetization directions of the fixed layer pattern 241A and the free layer pattern 243A. For example, the electrical resistance of the MTJ pattern 240A may be much greater when the magnetization directions of the fixed layer pattern 241A and the free layer pattern 243A are antiparallel than when they are parallel. As a result, the electrical resistance of the MTJ pattern 240A may be controlled by changing the magnetization direction of the free layer pattern 243A, which may be used as a data storage principle in a semiconductor device in accordance with the embodiment of the present disclosure.

Through the above process, the semiconductor device in accordance with the embodiment of the present disclosure may be fabricated. Referring back to FIG. 4B, a semiconductor device including the second substrate 200, the lower electrode contact 210, the MTJ pattern 240A including the fixed layer pattern 241A, the tunnel barrier layer pattern 242A, and the free layer pattern 243A, and the inter-layer dielectric layer 220 covering a sidewall of the lower electrode contact 210 may be fabricated in accordance with the embodiment of the present disclosure.

The embodiment of the present disclosure suggests a method of forming the MTJ pattern 240A by using an imprinting process, and the method for fabricating a semiconductor device in accordance with the embodiment of the present disclosure may solve the problems occurring in a general ion beam etching (IBE) process and improve the characteristics of the MTJ pattern 240A. The general method of patterning the MTJ pattern 240A may form a patterned MTJ pattern 240A by the IBE process. However, this method has limitations in precise etching due to insufficient process margins, electrical short circuit, referred to as a shorting failure rate (SFR) defects, damage to the sidewall of the MTJ pattern 240A, formation of a tapered MTJ pattern 240A, and limitation in the incident angle of an argon (Ar) beam in a narrow pitch region.

Accordingly, the semiconductor device and the method for fabricating the same in accordance with the embodiment of the present disclosure may be able to form an MTJ pattern 240A having a structure that the sidewalls of a right-angled MTJ pattern 240A, that is, the sidewalls of the fixed layer pattern 241A, the tunnel barrier layer pattern 242A and the free layer pattern 243A, are aligned perpendicularly to the plane of the second substrate 200, rather than an MTJ layer of a tapered structure, through the imprinting process using the stamper 140. According to the embodiment of the present disclosure, it is possible to provide a structure of an MTJ layer which is optimized for the operation characteristics of a memory cell by forming the sidewall of the MTJ pattern 240A not in a tapered structure but in a right-angled structure, and to facilitate the tuning of the characteristics of the MTJ pattern 240A. This right-angled structure may provide optimal conditions for controlling the magnetic and electrical characteristics of the MTJ pattern 240A.

Additionally, since the ion beam etching process is not used in the method for fabricating the semiconductor device in accordance with the embodiment of the present disclosure, damage to the sidewall of the MTJ pattern 240A may not occur, and damage to the sidewall of the MTJ pattern 240A may be prevented. As a result, the electrical short circuit defect may be reduced to improve the reliability of the MTJ pattern 240A. Also, by forming the MTJ pattern 240A not by an ion beam etching process but by an imprinting process, the MTJ pattern 240A may be precisely formed even in a narrow pitch region where it is difficult to perform an etching process due to the limitation in the incident angle of the argon (Ar) beam. This is advantageous for designing a high-density MTJ array and suitable for the next-generation small-size semiconductor devices. By eliminating the ion beam etching process, it is possible to simplify the process, reduce the equipment and operating costs, improve productivity, and increase cost efficiency.

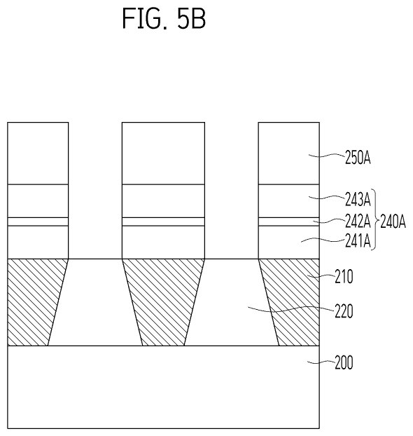

FIGS. 5A and 5B are cross-sectional views illustrating a semiconductor device and a method for fabricating the same in accordance with another embodiment of the present disclosure. Detailed description on the parts that are substantially the same as those in the embodiment of the present disclosure described earlier is omitted herein.

Referring to FIG. 5A, a memory layer may be formed over the lower electrode contact 210 exposed in the recessed portion between the resist patterns 230A formed in FIG. 3D. In other words, the MTJ layer 240 including a fixed layer 241, a tunnel barrier layer 242, and a free layer 243 may be formed sequentially over the lower electrode contact 210. A selector layer 250 may be additionally formed over the MTJ layer 240.

Referring to FIG. 5B, a lift-off process of removing the resist pattern 230A and leaving only the desired MTJ pattern 240A and a selector pattern 250A may be performed.

Through this process, the sidewall of the selector pattern 250A may be aligned perpendicularly to the plane of the second substrate 200 on the same plane as the sidewall of the MTJ pattern 240A. When the sidewall of the selector pattern 250A and the sidewall of the MTJ pattern 240A are aligned perpendicularly to the plane of the second substrate 200, the accuracy of the patterning may be increased and the consistency of the cell structure may be ensured. Also, the possibility of electrical failure due to the imbalance between the selector pattern 250A and the MTJ pattern 240A may be reduced, and the process variability may be minimized to ensure stable results during a mass production. Since the physical interference between cells is reduced due to the vertical alignment, data errors that may be caused due to signal interference may be reduced.

Additionally, when the sidewalls of the selector pattern 250A and the MTJ pattern 240A are aligned perpendicularly to the plane of the second substrate 200, the current path may be precisely defined, thereby preventing current leakage and excessive power consumption. In particular, it is effective in a Static Transfer Torque Magnetic Random Access Memory (STT-MRAM), and the like, which require high current control. This vertical alignment structure may minimize the gap between cells, thereby enabling a miniaturized high-density memory design, which may contribute to realizing a high-density memory in a next-generation semiconductor device. Also, the vertically aligned structure may increase the resistance uniformity between the selector pattern 250A and the MTJ pattern 240A, which may not only increase the reliability of a cell operation, but also reduce the deviation of the critical current and the switching voltage, thereby improving the operation characteristics. This may extend the lifespan of the semiconductor device and optimize the performance of the semiconductor device.

The selector pattern 250A may be realized as a thin layer in the memory cell and may have a function of controlling electrical access to one memory cell among the arrayed memory cells while preventing current leakage that may occur between the memory cells that share a first interconnection or a second interconnection. To this end, the selector pattern 250A may have threshold switching characteristics of blocking off a current or holding the current to hardly flow when the level of the voltage supplied to the upper and lower portions of the selector pattern 250A is less than the level of a predetermined threshold voltage, and then letting the current rapidly flow when the level of the voltage is greater than or equal to the level of the threshold voltage. In other words, the selector pattern 250A may be turned on when the level of the voltage is greater than or equal to the level of the threshold voltage and may be turned off when the level of the voltage is less than the level of the threshold voltage.

The selector pattern 250A may include a dielectric material into which a dopant is implanted. The dielectric material included in the selector pattern 250A may include a silicon oxide layer or an amorphous silicon layer. The dopant doped into the selector pattern 250A may include an N-type or P-type dopant, and may be implanted by an ion implantation process. The dopant may include, for example, at least one selected from the group including boron (B), nitrogen (N), carbon (C), phosphorus (P), arsenic (As), aluminum (Al), and germanium (Ge). In accordance with embodiments of the present disclosure and a dielectric material and dopant selected from the above, all of the advantages described in the embodiment of the present disclosure described above may be obtained.

The second substrate 200, the lower electrode contact 210, the inter-layer dielectric layer 220, and the MTJ pattern 240A including a fixed layer pattern 241A, a tunnel barrier layer pattern 242A, and a free layer pattern 243A illustrated in FIG. 5B may correspond to the second substrate 200, the lower electrode contact 210, the inter-layer dielectric layer 220, and the MTJ pattern 240A including the fixed layer pattern 241A, the tunnel barrier layer pattern 242A, and the free layer pattern 243A illustrated in FIG. 4B, respectively. Therefore, detailed description on the part corresponding to that of the process structure of FIG. 4B described earlier will be omitted.

Although the embodiment of the present disclosure illustrates only the MTJ pattern 240A and the selector pattern 250A between the resist patterns 230A, through a method for fabricating a semiconductor device in accordance with another embodiment of the present disclosure, a memory cell including diverse layers may be formed by burying diverse material layers between the resist patterns 230A. For example, a first electrode layer may be further disposed below the selector layer 250 and a second electrode layer may be further disposed over the selector layer 250, and a first electrode layer pattern and a second electrode layer pattern may be further formed by removing the resist pattern 230A. In this case, the sidewalls of the first electrode layer pattern and the second electrode layer pattern may be aligned perpendicularly to the plane of the second substrate 200 on the same plane as the sidewalls of the MTJ pattern 240A and the selector pattern 250A. The first electrode layer pattern and the second electrode layer pattern may include a titanium nitride (TiN) thin layer.

The first electrode layer pattern and the second electrode layer pattern may have a function of transferring a voltage or current required for an operation of the memory cell. The first electrode layer pattern may have a function of electrically connecting the selector pattern 250A and the MTJ pattern 240A to each other while physically separating them from each other. The first electrode layer pattern or the second electrode layer pattern may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or a combination thereof. Also, the first electrode layer pattern or the second electrode layer pattern may include a carbon electrode. For example, the first electrode layer pattern disposed below the selector pattern 250A may include titanium nitride (TiN), and the second electrode layer pattern disposed over the selector pattern 250A may include a carbon (C) electrode. Also, for example, the upper and lower positions of the memory layer including the selector pattern 250A and the MTJ pattern 240A may be switched with each other. Also, for example, the memory cell may further include one or more layers to improve the characteristics or the process.

Additionally, a silicon nitride (SiN) thin layer may be further included at the interface between the first electrode layer pattern and the selector pattern 250A, and a carbon (C) thin layer may be further included at the interface between the selector pattern 250A and the second electrode layer pattern. Each of the silicon nitride (SiN) thin layer and the carbon (C) thin layer may enhance the chemical stability at the interface and prevent physical damage. Since the silicon nitride (SiN) thin layer has excellent electrical insulation and chemical durability, it may be able to suppress the interface reaction, such as oxidation or diffusion, between the first electrode layer pattern and the selector pattern 250A. Also, since the carbon thin layer has excellent heat-resistance and wear resistance, it may be able to reduce the mechanical damage at the interface between the selector pattern 250A and the second electrode layer pattern and prevent interface deterioration. Also, with its excellent insulation characteristics, the silicon nitride (SiN) thin layer may minimize the current leakage, and stabilize the electrostatic capacitance at the interface, thereby reducing electrical noise. Also, the carbon thin layer may efficiently maintain the flow of the current between the selector pattern 250A and the second electrode layer pattern by providing a low electrical resistance and a high conductivity.

Additionally, according to an embodiment, an intermediate layer may be further disposed between the fixed layer 241 and the tunnel barrier layer 242, and an intermediate layer pattern may be further formed by removing the resist pattern 230A. The intermediate layer pattern may be a magnetic layer that is closest to the tunnel barrier layer pattern 242A, and the intermediate layer pattern may include Co, Fe, Ni, B, a noble metal, or a combination thereof. As used herein, the noble metal may include, for example, platinum (Pt), palladium (Pd), gold (Au), or silver (Ag).

According to the embodiment of the present disclosure, the semiconductor device and the method for fabricating the same may solve the problem of a general ion beam etching (IBE) process through an imprinting process to prevent the limitation in securing process margins, overcome the limitation in the incident angle of an argon (Ar) beam, prevent the electrical short circuit defect of an MTJ pattern and physical damage to the MTJ sidewall, and precisely tune the characteristics of the MTJ pattern by forming the MTJ pattern having a rectangular cross-section.

While the present disclosure has been described with respect to the specific embodiments, it will be apparent to those skilled in the art that various changes and modifications may be made without departing from the spirit and scope of the invention as defined in the following claims.

What is claimed is:

1. A semiconductor device, comprising:
a substrate; and
a memory layer formed over the substrate,
wherein the memory layer includes
a magnetic tunnel junction (MTJ) pattern, including a plurality of magnetic layer patterns and a tunnel barrier layer pattern, and
wherein sidewalls of the magnetic layer patterns and the tunnel barrier layer pattern are aligned perpendicularly to a plane of the substrate.

2. The semiconductor device of claim 1, further comprising:
a selector pattern,
wherein a sidewall of the selector pattern is aligned perpendicularly to a plane of the substrate on a same plane as a sidewall of the MTJ pattern.

3. The semiconductor device of claim 2, further comprising:
a first electrode layer pattern disposed below the selector pattern and
a second electrode layer pattern disposed over the selector pattern.

4. The semiconductor device of claim 3, wherein sidewalls of the first electrode layer pattern and the second electrode layer pattern are aligned perpendicularly to a plane of the substrate on the same plane as the sidewall of the MTJ pattern.

5. The semiconductor device of claim 3, wherein the first electrode layer pattern and the second electrode layer pattern include a titanium nitride (TiN) thin layer.

6. The semiconductor device of claim 3, further comprising:
a silicon nitride (SiN) thin layer at an interface between the first electrode layer pattern and the selector pattern, and
a carbon (C) thin layer at an interface between the selector pattern and the second electrode layer pattern.

7. The semiconductor device of claim 1, wherein the magnetic layer patterns include:
a free layer pattern having a changeable magnetization direction, and
a fixed layer pattern having a fixed magnetization direction.

8. The semiconductor device of claim 7, further comprising:
an intermediate layer pattern interposed between the fixed layer pattern and the tunnel barrier layer pattern.

9. The semiconductor device of claim 8, wherein the intermediate layer pattern includes cobalt (Co), iron (Fe), nickel (Ni), boron (B), a noble metal, or a combination thereof.

10. A method for fabricating a semiconductor device, comprising:
forming a guide pattern having a resist pattern arrayed over a substrate by an imprinting process;
forming a memory layer in a recessed portion of the resist pattern; and
forming a memory layer pattern by removing the guide pattern.

11. The method of claim 10, wherein the forming of the memory layer pattern includes forming a memory layer pattern.

12. The method of claim 11, wherein the forming of the memory layer pattern includes forming a magnetic tunnel junction (MTJ) pattern including a plurality of magnetic layer patterns.

13. The method of claim 10, further comprising:
forming a selector layer over the memory layer that is formed in the recessed portion; and
forming a selector pattern by removing the guide pattern.

14. The method of claim 10, wherein the forming of the guide pattern includes:
forming a stamper having an engraved pattern whose surface is covered with a conductive layer;
preparing an etch target layer having a resist layer formed in an upper portion of the etch target layer;
transferring a shape of the pattern of the stamper to the resist layer by combining the stamper and the etch target layer to have the conductive layer and the resist layer face each other; and
forming a resist pattern over the etch target layer by removing the stamper.

15. The method of claim 14, wherein the conductive layer of the stamper includes at least one selected from a group including nickel (Ni), copper (Cu), silver (Ag), and gold (Au).

16. The method of claim 14, wherein the resist layer includes a thermosetting resin or an ultraviolet (UV)-curable resin.

17. The method of claim 14, wherein the conductive layer of the stamper is formed by sputtering, electroplating, chemical vapor deposition, or evaporation deposition.

18. The method of claim 10, wherein the guide pattern includes a lower electrode contact.

19. The method of claim 13, further comprising:
forming a first electrode layer below the selector layer formed over the memory layer that is formed in the recessed portion, and forming a second electrode layer over the selector layer; and
forming a first electrode layer pattern and a second electrode layer pattern by removing the guide pattern.

20. The method of claim 19, wherein each of the first electrode layer pattern and the second electrode layer pattern includes a titanium nitride (TiN) thin layer.
